(19) United States
(12) Patent Application Publication
(10) Pub. No.: US 2015/0325969 A1
(43) Pub. Date: Nov. 12, 2015

(54) DEVICE AND METHOD FOR SEPARATION OF A CRIMPED WIRE TERMINAL FROM A TAPE TERMINAL CARRIER STRIP

(71) Applicant: Starn Tool & Manufacturing Company, Meadville, PA (US)

(72) Inventors: John Matthew BELOVARAC, Cambridge Springs, PA (US); Jared Callahan, Meadville, PA (US)

(21) Appl. No.: 14/678,955

(22) Filed: Apr. 4, 2015

Related U.S. Application Data
(60) Provisional application No. 61/991,009, filed on May 9, 2014.

(51) Int. Cl. H01R 43/055; H05K 13/00

(52) U.S. Cl. CPC H01R 43/055; H05K 13/0092

(57) ABSTRACT

Devices and methods to facilitate separation of a crimped wire terminal from a tape terminal carrier strip. The devices and methods weaken the attachment between the crimped wire terminal and the tape terminal carrier strip to facilitate effective, efficient, and reliable removal of the crimped wire terminal from the tape terminal carrier strip.

### CROSS REFERENCE TO RELATED APPLICATION

This application claims priority from U.S. Provisional Patent Application 61/991,009 filed on May 9, 2014. That Provisional Patent Application is herein incorporated by reference in its entirety.

### FIELD OF THE INVENTION

The invention relates generally to the field of electrical terminal crimping machines and methodologies used in the crimp connection process. In particular, the invention relates to a device and method that facilitate effective, efficient, and reliable separation of a crimped wire terminal from a tape terminal carrier strip.

### BACKGROUND

In the electrical connector industry, a crimp connection is commonly used to fuse a wire to a wire terminal. A “wire” can be a single wire or a cable comprised of more than one wire. A wire terminal that has not yet been fused to a wire is referred to as an “uncrimped wire terminal.” A wire terminal that has been fused to a wire is referred to as a “crimped wire terminal.”

Individuals desiring to create numerous crimp connections typically utilize an electrical terminal crimping machine in conjunction with a tape terminal carrier strip. A tape terminal carrier strip is a flexible tape that has numerous wire terminals attached to the tape terminal carrier strip and positioned side-by-side at evenly spaced intervals.

A conventional electrical terminal crimping machine has a power system and an applicator. The power system produces or conducts the power necessary for movement of the electrical terminal crimping machine's parts and can include electric, pneumatic, or hydraulic power systems.

The applicator has a feed mechanism, press assembly, and anvil, each connected to the applicator. The feed mechanism is attached to the applicator via standard fasteners and feeds the tape terminal carrier strip through the applicator. The press assembly is attached to the applicator via standard fasteners, is positioned vertically above the anvil, and has a press that is capable of engaging in vertical upward and downward motion. The anvil is attached to the applicator via a mounting hole and is located directly under the press assembly. The anvil has a crimp surface located on the top surface of the anvil.

As is known in the art, to create a crimp connection that fuses an uncrimped wire terminal to a wire, the feed mechanism advances the tape terminal carrier strip so that the uncrimped wire terminal, attached to the tape terminal carrier strip, is positioned directly below the press and rests on top of the crimp surface of the anvil. The terminal end of a wire is inserted into the receiving end of the uncrimped wire terminal. The press then moves in a downward vertical direction toward the anvil. The bottom surface of the press contacts the top surface of the uncrimped wire terminal, continues in the downward vertical direction, and applying downward force, momentarily sandwiches the uncrimped wire terminal between the bottom surface of the depressed press and the crimp surface of the anvil, creating a crimp connection that fuses the wire terminal to the wire. The press then moves vertically upward to return to its original position.

The feed mechanism then advances the tape terminal carrier strip laterally across the top surface of the anvil so that the newly crimped wire terminal, now fused to the wire, is no longer positioned directly below the press, thereby allowing the next successive uncrimped wire terminal attached to the tape terminal carrier strip to be positioned on the crimp surface of the anvil and located directly under the press.

After the crimp connection occurs, the crimped wire terminal, now fused to the wire, must be removed from the tape terminal carrier strip for industry use. In a conventional electrical terminal crimping machine, and with the conventional crimping method, after the fusion of the wire terminal to the wire and advancement of the tape terminal carrier strip, the newly crimped wire terminal remains in a position that is perpendicular to the tape terminal carrier strip and remains tightly attached to the tape terminal carrier strip.

Conventional electrical terminal crimping machine devices and crimp connection methods do not facilitate effective, efficient, or reliable removal of the crimped wire terminal from its attachment to the tape terminal carrier strip. Known adaptations for removal of a crimped wire terminal from the tape terminal carrier strip include use of a cutting tool to weaken or break the attachment between the crimped wire terminal and the tape terminal carrier strip, application of manual force to the wire to weaken or break the attachment between the crimped wire terminal and the tape terminal carrier strip, and adaptations to the feed mechanism. However, each one of these known adaptations suffers from one or more of the following disadvantages: non-productive downtime for the operator, damage to the crimped wire terminal or connected wire, damage to or jamming of the feed mechanism or tape terminal carrier strip.

Therefore, there is a need to adapt the electrical terminal crimping machine, as well as the conventional methods utilized to remove a crimped wire terminal from a tape terminal carrier strip, to facilitate effective, efficient, and reliable removal of a crimped wire terminal from the tape terminal carrier strip.

### BRIEF SUMMARY

The preferred embodiments involve devices and methods for providing effective, efficient, and reliable removal of a crimped wire terminal from a tape terminal carrier strip. The devices and methods utilize an applicator for an electrical terminal crimping machine that has an anvil with a separation assistance device, in combination with advancement of the tape terminal carrier strip by the feed mechanism, to weaken the attachment between a crimped wire terminal and the tape terminal carrier strip in order to facilitate separation of a crimped wire terminal from the tape terminal carrier strip.

In one preferred embodiment, the separation assistance device has a ramp. In another preferred embodiment, the separation assistance device has a traveling ramp that is able to move in the vertical direction. In another preferred embodiment, the separation assistance device has a cylindrical pin.

A method is also provided for weakening the attachment between a crimped wire terminal and a tape terminal carrier strip to facilitate removal of the crimped wire terminal from the tape terminal carrier strip. The method generally includes: (1) providing a tape terminal carrier strip that has at least one uncrimped wire terminal attached to the tape terminal carrier strip, (2) feeding the tape terminal carrier strip through an electrical terminal crimping machine so that an uncrimped wire terminal rests on the top surface of an anvil and directly under a press, (3) inserting the terminal end of a wire into the receiving end of the uncrimped wire terminal positioned on the top surface of the anvil, (4) the downward vertical motion of the press, (5) the press applying downward vertical force to the top surface of the uncrimped wire terminal and momentarily sandwiching the uncrimped wire terminal and the inserted wire between the bottom surface of the depressed press and the top surface of the anvil, (6) the creation of a crimp connection that fuses the wire to the wire terminal, (7) the vertical upward movement of the press so that the press returns to its original position, (8) advancement of the tape terminal carrier strip so that the tape terminal carrier strip moves laterally across the top surface of the anvil, and (9) contact between a separation assistance device located on the anvil and the crimped wire terminal attached to the advancing tape terminal carrier strip so that the attachment between the crimped wire terminal and the tape terminal carrier strip is weakened.

In one preferred embodiment, the contact between the separation assistance device and the newly crimped wire terminal attached to the advancing tape terminal carrier strip causes the newly crimped wire terminal to move from a position in which the newly crimped wire terminal is perpendicular to the tape terminal carrier strip to a position in which the newly crimped wire terminal is positioned at non-perpendicular angle in relation to the tape terminal carrier strip.

### BRIEF DESCRIPTION OF THE DRAWINGS

A complete understanding of the features, aspects, and advantages of the preferred embodiments will be obtained from the following description when taken in connection with the accompanying drawing figures, wherein like reference numerals identify the same parts throughout.

FIG. 1 is a front view of an electrical terminal crimping machine with an applicator that has one preferred embodiment, illustrating numerous uncrimped wire terminals all attached side-by-side to a tape terminal carrier strip, the leading uncrimped wire terminal resting on the top surface of the anvil in preparation for the crimp connection process.

FIG. 2 is a perspective front view of the applicator of FIG. 1.

FIG. 3 is a perspective front view of the applicator of FIG. 2 and a perspective view of one preferred embodiment.

FIG. 4 is a perspective front view of one preferred embodiment.

FIG. 5 is a zoomed-in front view of the electrical terminal crimping machine of FIG. 1.

FIG. 6 is a perspective side view of an electrical terminal crimping machine with an applicator that has one preferred embodiment, illustrating insertion of the terminal end of a wire into the receiving end of an uncrimped wire terminal in preparation for the crimp connection process.

FIG. 7 is a perspective side view of an electrical terminal crimping machine with an applicator that has one preferred embodiment, illustrating the creation of a crimp connection between a wire terminal and wire by the downward vertical motion of the press.

FIG. 8 is a perspective side view of an electrical terminal crimping machine with an applicator that has one preferred embodiment, illustrating advancement of the tape terminal carrier strip after the creation of a crimp connection and contact between one preferred embodiment and the newly crimped wire terminal.

FIG. 9A is a perspective front view of another preferred embodiment.

FIG. 9B is a perspective front view of yet another preferred embodiment.

### DETAILED DESCRIPTION OF THE PREFERRED EMBODIMENTS

10 electrical terminal crimping machine
11 press assembly
12 applicator
13 press
14 tape terminal carrier strip
15 anvil
16 uncrimped wire terminal
17 feed mechanism
18 feed holes
22 key
24 mounting hole
28 separation assistance device
30 ramp
32 cylindrical pin
34 traveling ramp
36 wire
38 crimped wire terminal
40 crimp surface

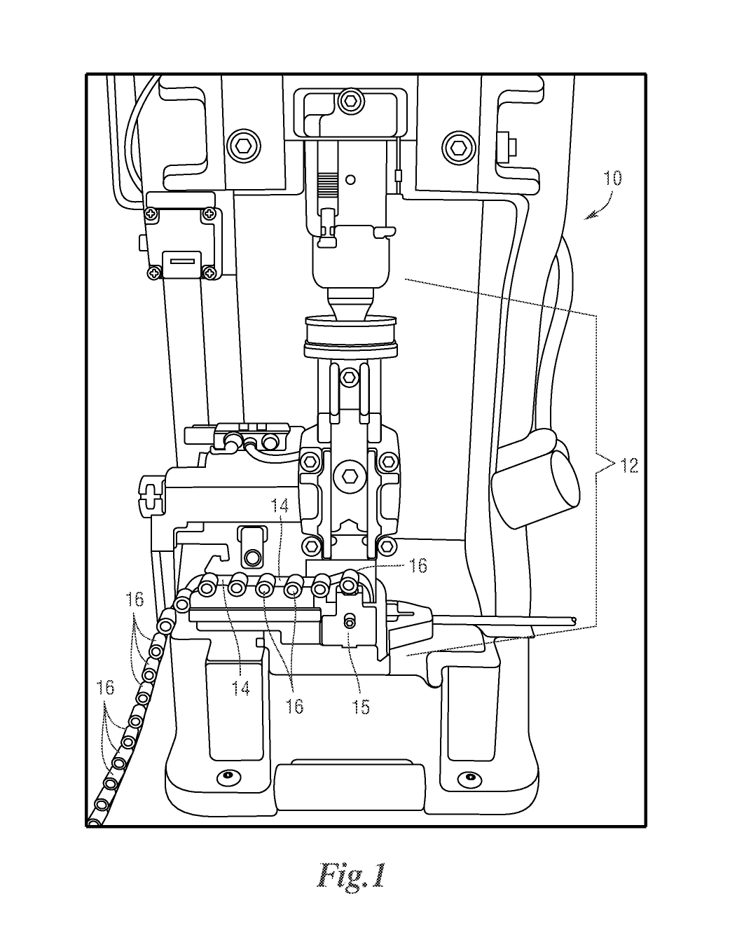

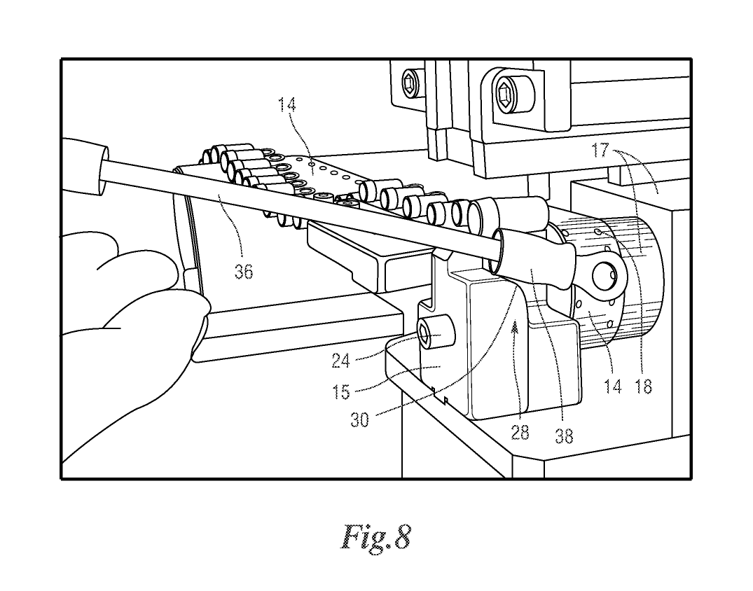

Referring now to the drawings, FIG. 1 shows an electrical terminal crimping machine, generally designated 10. The electrical terminal crimping machine 10 contains a power supply and an applicator 12. As shown in FIGS. 1 and 8, the applicator 12 has the various mechanical parts necessary to perform a crimp connection, including a feed mechanism 17. A tape terminal carrier strip 14 having numerous evenly-spaced uncrimped wire terminals 16, each attached to the tape terminal carrier strip 14, is attached to the applicator 12 via the feed mechanism 17.

The feed mechanism 17 feeds the tape terminal carrier strip 14 through the applicator 12 of the electrical terminal crimping machine 10. In one preferred embodiment, the feed mechanism 17 feeds the tape terminal carrier strip 14 through the applicator 12 of the electrical terminal crimping machine 10 via feed holes 18 located on the tape terminal carrier strip 14.

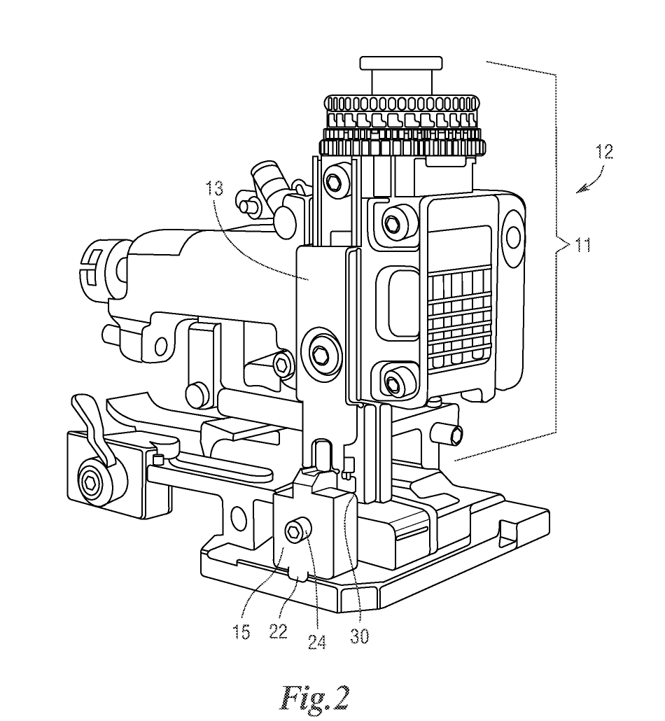

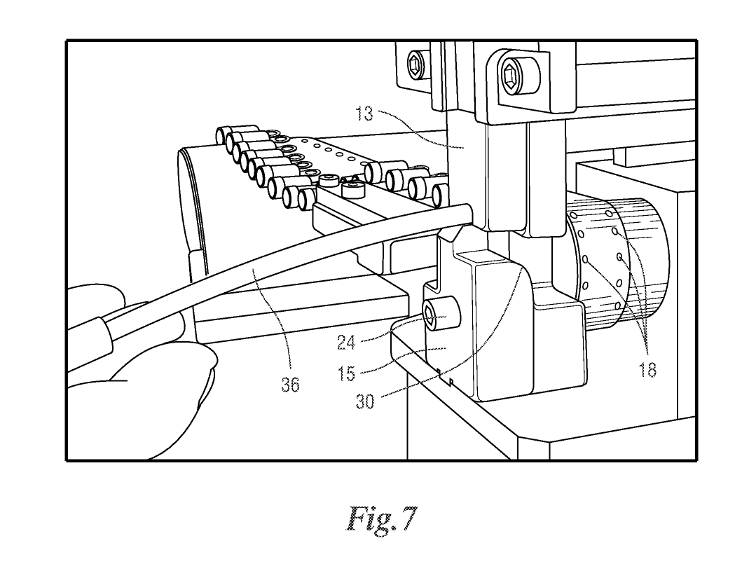

As shown in FIG. 2, the applicator 12 has a press assembly 11 and an anvil 15. The press assembly 11 is attached to the applicator 12 via at least one standard fastener. The press assembly 11 has a press 13 that is moveable in the vertical upward and downward directions as shown in FIG. 7.

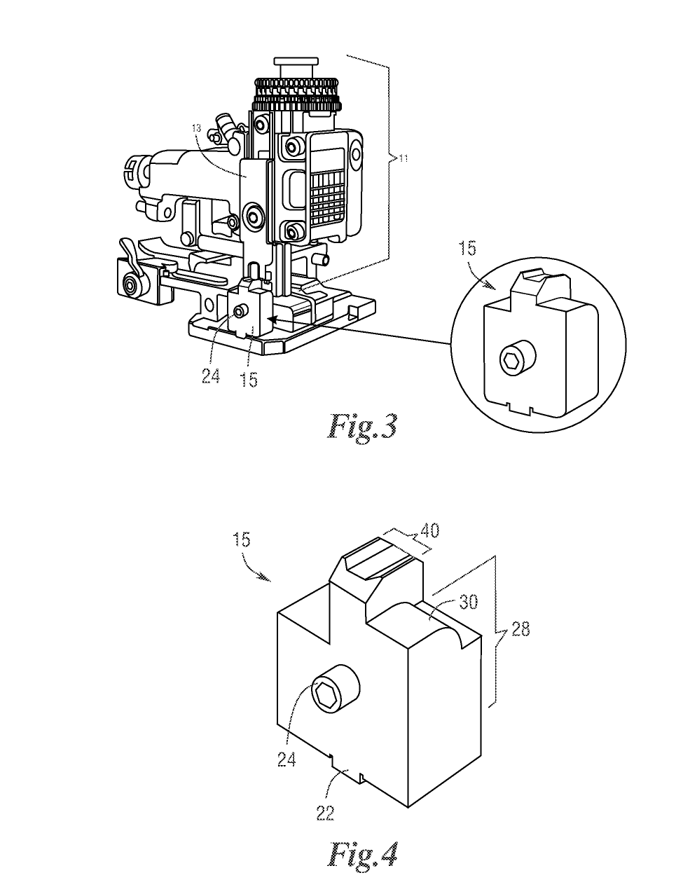

As shown in FIG. 3, the anvil 15 is attached to the applicator 12 via a mounting hole 24. As shown in FIG. 4, the anvil 15 has a key 22, a crimp surface 40, and a separation assistance device 28. The key 22 helps to ensure that the anvil 15 is properly attached to the applicator 12 and positioned directly under the press 13. The crimp surface 40 of the anvil 15 could correspond to the type, size, and shape of uncrimped wire terminal 16 attached to the tape terminal carrier strip 14.

In one preferred embodiment, the separation assistance device 28 has a ramp 30. In one preferred embodiment, the ramp 30 has a rounded element. There are various possibilities for the orientation and angles of the top surface of the ramp 30 depending on the type, size, and shape of the uncrimped wire terminal 16 and wire 36 utilized in the crimp connection process.

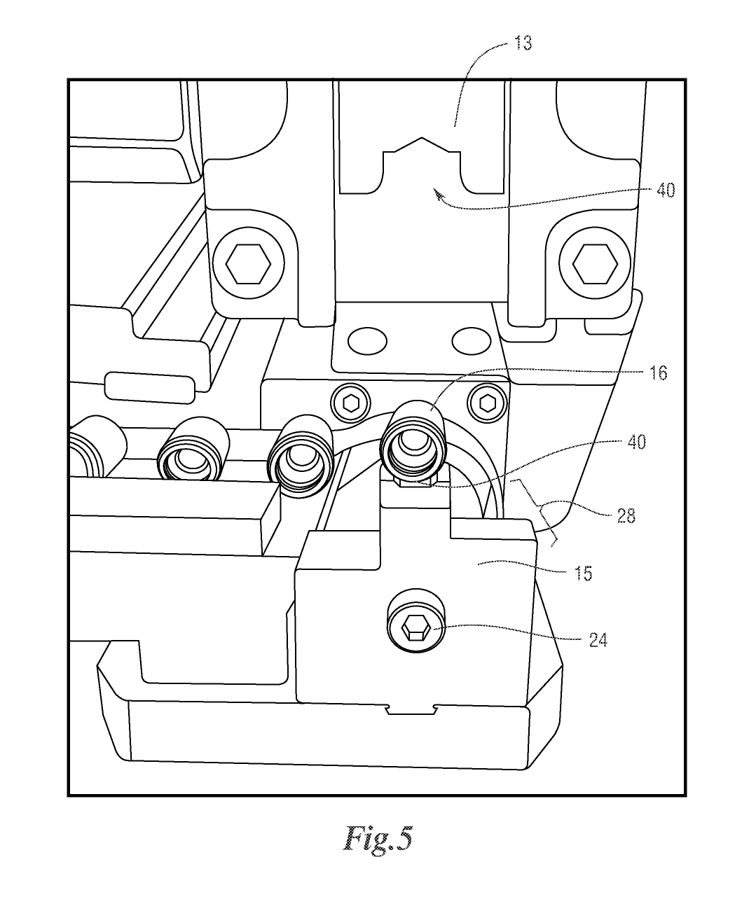

As shown in FIG. 5, during the crimp connection process, the tape terminal carrier strip 14 containing at least one uncrimped wire terminal 16, and sometimes numerous attached uncrimped wire terminals 16, is fed through the applicator 12 so that the leading uncrimped wire terminal 16 attached to the tape terminal carrier strip 14 rests on top of the crimp surface 40 of the anvil 15 in preparation for the crimp connection process. In one preferred embodiment, the press 13 also has a crimp surface 40. The crimp surface 40 of the press could correspond to the type, size, and shape of uncrimped wire terminal 16.

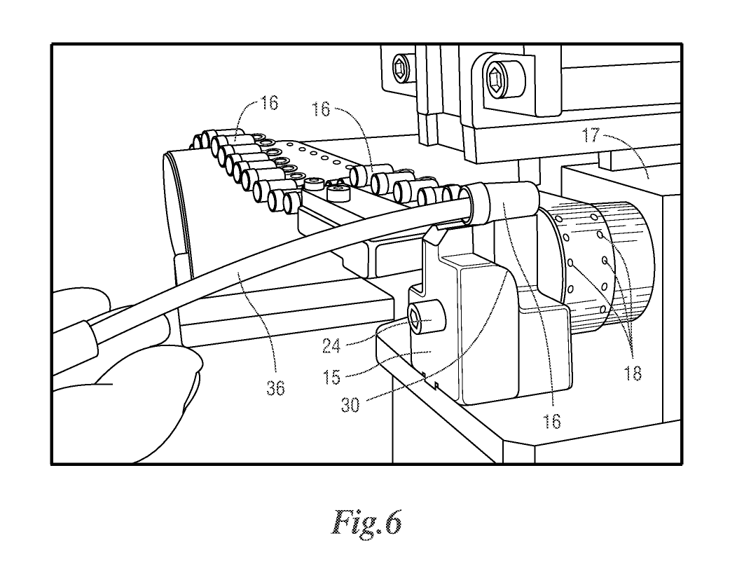

As shown in FIG. 6, in general operation of an electrical terminal crimping machine 10, an operator places the terminal end of a wire 36 into the receiving end of an uncrimped wire terminal 16 that is resting on top of the crimp surface 40 of the anvil 15 in preparation for the crimp connection process.

As shown in FIG. 7, the press 13 moves vertically downward toward the anvil 15, contacts the top surface of the uncrimped wire terminal 16, and applying downward force, momentarily sandwiches the uncrimped wire terminal 16 between the bottom surface of the depressed press 13 and the crimp surface 40 of the anvil 15, thereby creating a crimp connection and fusing the uncrimped wire terminal 16 to the wire 36.

As shown in FIG. 8, the press 13 then moves vertically upward to its original starting position while the feed mechanism 17 advances the tape terminal carrier strip 14 through the applicator 12 of the electrical terminal crimping machine 10, and moves the newly crimped wire terminal 38 laterally away from the crimp surface 40 of the anvil 15 and across the top surface of the anvil 15, thereby positioning the next successive uncrimped wire terminal 16 attached to the tape terminal carrier strip 14 directly on top of the crimp surface 40 of the anvil 15 in preparation for the crimp connection process. During this lateral advancement motion initiated by the feed mechanism 17, the separation assistance device 28 contacts the crimped wire terminal 38 that is still attached to the tape terminal carrier strip 14, and applies angular force to the newly crimped wire terminal 38. This angular force applied by the separation assistance device 28 weakens the crimped wire terminal's 38 attachment to the tape terminal carrier strip 14.

As shown in FIG. 8, in one preferred embodiment, at the end stage of the lateral advancement movement initiated by the feed mechanism 17, the newly crimped wire terminal 38 rests on top of the separation assistance device 28 so that the newly crimped wire terminal 38 is positioned at a non-perpendicular angle in relation to the tape terminal carrier strip 14 and prepared for separation from the tape terminal carrier strip 14. The newly crimped wire terminal 38 that has a weakened attachment to the tape terminal carrier strip 14 is then separated from the tape terminal carrier strip 14 either by manual force or other separating means.

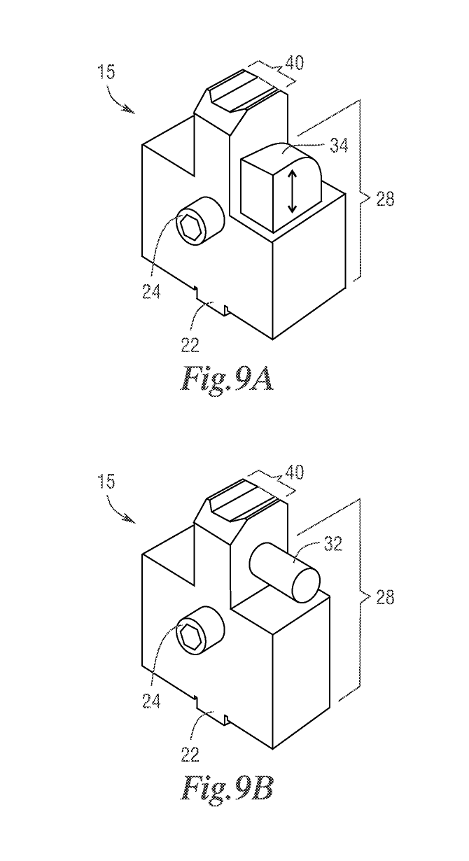

As shown in FIG. 9A, another preferred embodiment has an anvil 15 with a separation assistance device 28 that has a traveling ramp 34. The traveling ramp 34 is able to move in the vertical direction, and is able to be under various tensions. The traveling ramp 34 applies an upward angular force to the crimped wire terminal 38 as the crimped wire terminal 38 moves laterally across the top surface of the anvil 15 so that the crimped wire terminal's 38 attachment to the tape terminal carrier strip 14 is weakened in preparation for removal of the crimped wire terminal 38 from the tape terminal carrier strip 14. In one preferred embodiment, the top surface of the traveling ramp 34 has a rounded element as shown in FIG. 9A. There are various possibilities for the orientation and angles of the top surface of the traveling ramp 34 depending on the type, shape, and size of the uncrimped wire terminal 16 and wire 36 utilized in the crimp connection process. In one preferred embodiment, the traveling ramp 34 is limited by a mechanical stop (not shown) so that the separation assistance device 28 is prevented from interfering with the crimped wire terminal 38 and attached wire 36.

As shown in FIG. 9B, another preferred embodiment has an anvil 15 with a separation assistance device 28 that has a cylindrical pin 32. The cylindrical pin 32 could be positioned laterally to the crimp surface 40 of the anvil 15 and below the top surface of the crimp surface 40 of the anvil 15 so that the cylindrical pin 32 applies a force to the crimped wire terminal 38 as the crimped wire terminal 38 moves laterally across the top surface of the separation assistance device 28 and thereby weakens the attachment of the crimped wire terminal 38 to the tape terminal carrier strip 14. There are various possibilities for the orientation of the cylindrical pin 32 depending on the type, shape, and size of the uncrimped wire terminal 16 and wire 36 utilized in the crimp connection process.

The present examples and embodiments are to be considered in all respects as illustrative and not restrictive, and the invention is not to be limited to the details given herein.

What is claimed is:

1. An applicator for an electrical terminal crimping machine, said applicator comprising:
A feed mechanism, said feed mechanism being capable of advancing a tape terminal carrier strip, said tape terminal carrier strip having at least one wire terminal attached to said tape terminal carrier strip;
A press assembly having a press, said press being constructed so as to be moveable in the vertical direction; and
An anvil, said anvil being positioned vertically below said press assembly and having a crimp surface and a separation assistance device, said separation assistance device being located adjacent to said crimp surface.

2. The applicator recited in claim 1, wherein said separation assistance device has a ramp.

3. The applicator recited in claim 2, wherein said ramp has a rounded element.

4. The applicator recited in claim 1, wherein said separation assistance device has a traveling ramp.

5. The applicator recited in claim 4, wherein said traveling ramp is movable in the vertical direction.

6. The applicator recited in claim 4, wherein said traveling ramp has a rounded element.

7. The applicator recited in claim 1, wherein said separation assistance device has a cylindrical pin.

8. The applicator recited in claim 1, wherein said anvil has a mounting hole.

9. The applicator recited in claim 1, wherein said anvil has a key.

10. A method for separating a crimped wire terminal from a tape terminal carrier strip, comprising:
a. providing said tape terminal carrier strip which has at least one uncrimped wire terminal attached to said tape terminal carrier strip;
b. feeding said tape terminal carrier strip through an electrical terminal crimping machine so that said uncrimped wire terminal rests on the top surface of an anvil and directly under a press;
c. inserting a wire into a receiving end of said uncrimped wire terminal;
d. depressing said press in the downward vertical direction toward said anvil, whereby said uncrimped wire terminal will be fused to said wire to create a crimped wire terminal; and
e. advancing said tape terminal carrier strip so that a separation assistance device positioned on said anvil applies a force to said crimped wire terminal, whereby said force weakens the attachment between said crimped wire terminal and said tape terminal carrier strip.

11. A method as recited in claim 10, wherein said separation assistance device has a ramp.

12. A method as recited in claim 11, wherein said ramp has a rounded element.

13. A method as recited in claim 10, wherein said separation assistance device has a traveling ramp, said traveling ramp being movable in the vertical direction.

14. A method as recited in claim 13, wherein said traveling ramp has a rounded element.

15. A method as recited in claim 10, wherein said separation assistance device has a cylindrical pin.

16. An applicator for an electrical terminal crimping machine, said applicator comprising:
means for advancing a tape terminal carrier strip, said tape terminal carrier strip having at least one uncrimped wire terminal attached to said tape terminal carrier strip;
means for creating a crimp connection between said uncrimped wire terminal and a wire whereby the uncrimped wire terminal becomes a crimped wire terminal that is fused to the wire; and
means for weakening the attachment between said crimped wire terminal and said tape terminal carrier strip.
